(19) United States
(12) Patent Application Publication
(10) Pub. No.: US 2012/0012253 A1
(43) Pub. Date: Jan. 19, 2012

(54) PLASMA SHIELD FOR ELECTRODE

(76) Inventors: Wayne Robert Simpson, San Jose, CA (US); Soon Seok Han, Gyeonggi-do (KR)

(21) Appl. No.: 13/182,179

(22) Filed: Jul. 13, 2011

(30) Foreign Application Priority Data
Jul. 13, 2010 (KR) 10-2010-0067610

(51) Int. Cl. C23C 16/50; H01L 21/3065

(52) U.S. Cl. 156/345.33; 118/723 R

(57) ABSTRACT

Provided is a plasma shield for an electrode capable of preventing generation of particles by providing plasma shields at inner and outer diameter sides of an adhesive formed of elastomer for attaching a gas injection plate to an injection plate support member to protect the adhesive.

The electrode includes a gas injection plate having a porous plate structure in which a plurality of gas injection holes are formed, an injection plate support member configured to maintain the gas injection plate attached to one side of a plasma chamber, and an adhesive formed of elastomer and attaching the injection plate support member to an upper surface of the gas injection plate. The improvement includes plasma shields having an annular shape corresponding to inner and outer diameters of the adhesive formed of the elastomer, installed adjacent to inner and outer diameter surfaces of the adhesive formed of the elastomer, and sealing the adhesive formed of the elastomer and disposed between the gas injection plate and the injection plate support member to prevent contact with particles generated while a plasma chamber is operated.

### CROSS-REFERENCE TO RELATED APPLICATION

The present application claims priority under 35 U.S.C. §119 to Korean Patent Application No. 10-2010-0067610 (filed on Jul. 13, 2010), which is hereby incorporated by reference in its entirety.

### BACKGROUND

1. Field of the Invention

The present invention relates to a plasma shield for an electrode, and more particularly, to a plasma shield for an electrode capable of preventing generation of particles due to adhesive by providing plasma shields at inner and outer diameter sides of an adhesive formed of elastomer for attaching a gas injection plate to an injection plate support member to protect the adhesive.

2. Discussion of Related Art

In general, a plasma chamber is one piece of equipment used to etch a workpiece in process or perform a plasma chemical vapor deposition process during processes of manufacturing general industrial products as well as processes of producing semiconductor parts such as a wafer.

The plasma chamber as described above is generally provided in various configurations and sizes according to workpieces. A plasma chamber shown in FIG. 1 is used to perform etching or deposition processes of semiconductor parts such as a wafer.

FIG. 1 is a view schematically showing configuration of a conventional plasma chamber, FIG. 2 is an exploded perspective view of a conventional electrode for a plasma chamber, and FIG. 3 is a cross-sectional view of the conventional electrode for a plasma chamber, which is assembled.

As shown in FIG. 1, a cathode 20 and an anode 30 for applying a high voltage are disposed at upper and lower parts of a plasma chamber 10 to oppose each other. A vacuum pump 12 is installed at one side of the plasma chamber 10 to evacuate the chamber to a vacuum state, and a gas injection port 14 is installed at the other side of the plasma chamber 10 to inject a reaction gas such as fluorine or nitrogen. In addition, in order to continuously cool the plasma chamber 10 exposed to a high pressure and high temperature state, a cooling water line 16 is installed at the cathode 20 to circulate cooling water.

When a high voltage is applied from a power supply 40 to the cathode 20 and the anode 30 in a state in which the plasma chamber 10 as described above is operated until the inside of the chamber enters a vacuum state and the reaction gas such as fluorine or nitrogen is simultaneously injected through the gas injection port 14, the inside of the chamber enters a plasma state. In this process, a workpiece such as a wafer is processed through an etching or deposition process by the reaction gas in a plasma state.

Meanwhile, in the plasma chamber 10, as shown in FIGS. 2 and 3, the cathode 20 generally includes a gas injection plate 22 having a porous plate structure in which a plurality of gas injection holes 22a are formed, and an injection plate support member 24 configured to maintain a state in which the gas injection plate 22 is attached to one side of the plasma chamber 10. The gas injection plate 22 and the injection plate support member 24, which are separately manufactured, are integrally adhered to each other by a separate adhesion process.

In other words, in order to attach the gas injection plate 22 to the injection plate support member 24, a double-sided adhesive 26 formed of elastomer is provided in an annular shape corresponding to a shape of a lower surface of the injection plate support member 24. The adhesive 26 is adhered to the lower surface of the injection plate support member 24 and an upper surface of the gas injection plate 22, and the support member 24 and the gas injection plate 22 are pressed to integrally attach the injection plate support member 24 on the gas injection plate 22.

However, in the conventional electrode for a plasma chamber, since the adhesive between the gas injection plate and the injection plate support member is exposed to the exterior, the adhesive may be separated by a gas injected at a high pressure or a physical attack of plasma and generate particles.

In addition, as described above, in the conventional electrode for a plasma chamber, since the adhesive between the gas injection plate and the injection plate support member is exposed to the exterior, when the adhesive separated by the high pressure gas or the plasma is introduced into the chamber, the inside of the chamber is contaminated and thus the workpiece is also contaminated.

Further, as described above, when the conventional electrode for a plasma chamber is contaminated with particles, during a process of cleaning the particles, a chemical cleaning agent may decrease adhesion of the elastomer and decrease a lifespan of the electrode.

Furthermore, since the elastomer, which is adhesive, of the conventional electrode for a plasma chamber is exposed to the exterior, decreasing resistance to the plasma, a down time of the electrode for a plasma chamber is decreased due to malfunction of the electrode, decreasing a rate of operation of the plasma chamber.

In addition, since the elastomer, which is adhesive, of the conventional electrode for a plasma chamber is exposed to the exterior, decreasing resistance to the plasma, the electrode for a plasma chamber must be frequently exchanged with a new one, leading to an increase in exchange cost.

### SUMMARY OF THE INVENTION

In order to solve the problems, the present invention is directed to a plasma shield for an electrode capable of preventing generation of particles by fixing plasma shields at inner and outer diameter sides of adhesive for attaching a gas injection plate to a gas injection plate support member to shield the adhesive from a high pressure gas or plasma.

The present invention is also directed to a plasma shield for an electrode capable of improving resistance against attacks of plasma by shielding the adhesive from the high pressure gas or plasma through configuration of the plasma shields at the inner and outer diameter sides of the adhesive.

The present invention is also directed to a plasma shield for an electrode capable of improving lifespan of an electrode for a plasma chamber by shielding the adhesive from the high pressure gas or plasma through configuration of the plasma shields at the inner and outer diameter sides of the adhesive.

The present invention is also directed to a plasma shield for an electrode capable of reducing exchange needs of the plasma shield for an electrode by shielding the adhesive from the high pressure gas or plasma through configuration of the plasma shields at the inner and outer diameter sides of the adhesive.

In example embodiments, in a plasma shield for an electrode, the electrode includes a gas injection plate having a porous plate structure in which a plurality of gas injection holes are formed, an injection plate support member configured to maintain the gas injection plate attached to one side of a plasma chamber, and an adhesive formed of elastomer and attaching the injection plate support member to an upper surface of the gas injection plate. The improvement includes plasma shields having an annular shape corresponding to inner and outer diameters of the adhesive formed of the elastomer, installed adjacent to inner and outer diameter surfaces of the adhesive formed of the elastomer, and sealing the adhesive formed of the elastomer and disposed between the gas injection plate and the injection plate support member to protect the adhesive from a high pressure gas and plasma and prevent generation of particles.

Meanwhile, the plasma shield may have an O-ring shape having a circular cross-section. In addition, the plasma shield may have a gasket shape having a rectangular cross-section.

Further, the plasma shields may be attached to a lower surface of the injection plate support member and an upper surface of the gas injection plate through adhesive elements, or may be disposed at inner and outer diameter sides of the adhesive to be fixed by adhesion of the gas injection plate and the injection plate support member due to the adhesive.

Furthermore, the plasma shield may be formed of any one of perfluoroelastomer (FFKM), viton perfluoroelastomer, silicon, and polyamide.

### BRIEF DESCRIPTION OF THE DRAWINGS

The above and other objects, features and advantages of the present invention will become more apparent to those of ordinary skill in the art by describing in detail example embodiments thereof with reference to the attached drawings, in which:

FIG. 1 is a view schematically showing configuration of a conventional plasma chamber;

FIG. 2 is an exploded perspective view of a conventional electrode for a plasma chamber;

FIG. 3 is a cross-sectional view of the conventional electrode for a plasma chamber, which is assembled;

FIG. 4 is an exploded perspective view of a plasma shield for an electrode in accordance with the present invention;

FIG. 5 is a cross-sectional view of the plasma shield for an electrode in accordance with the present invention, which is assembled;

FIG. 6A is a perspective view showing a plasma shield applied to the plasma shield for an electrode in accordance with the present invention; and

FIG. 6B is a perspective view showing another plasma shield applied to the plasma shield for an electrode in accordance with the present invention.

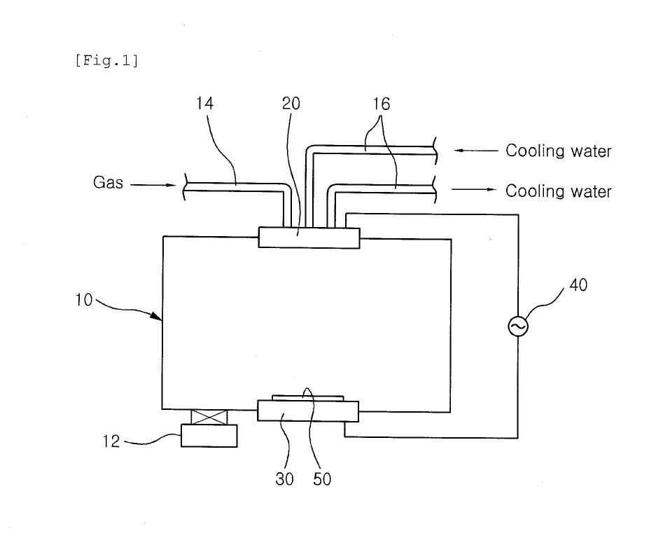

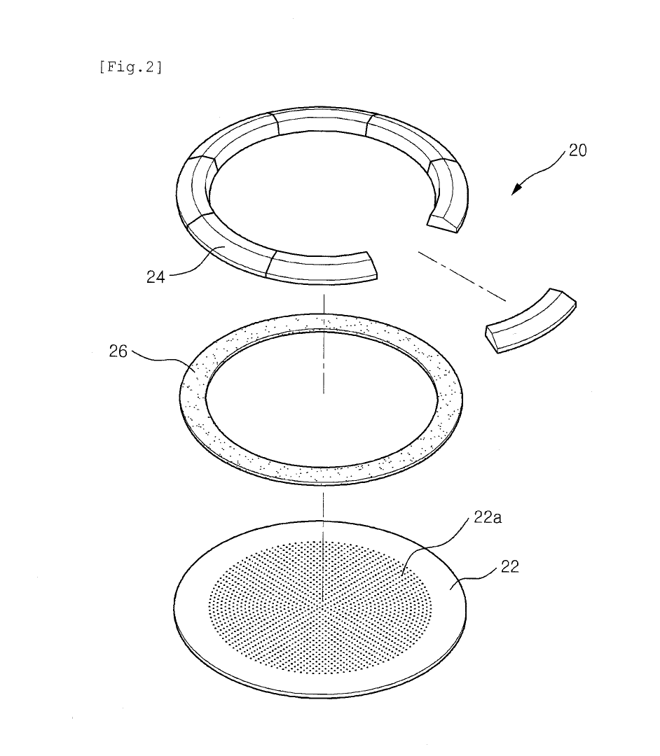

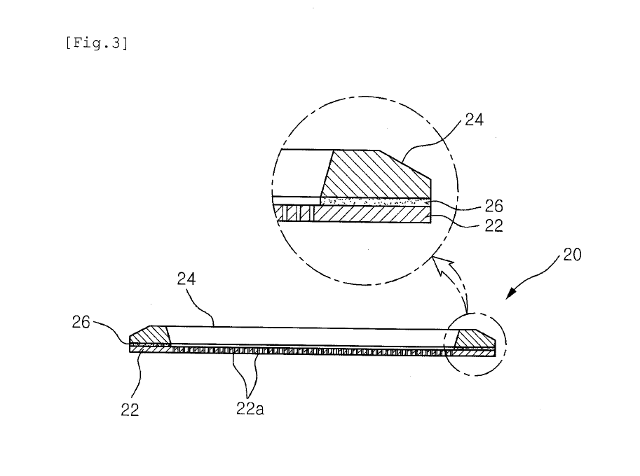

### DETAILED DESCRIPTION OF EXAMPLE EMBODIMENTS

Hereinafter, a plasma shield for an electrode in accordance with an example embodiment of the present invention will be described in detail.

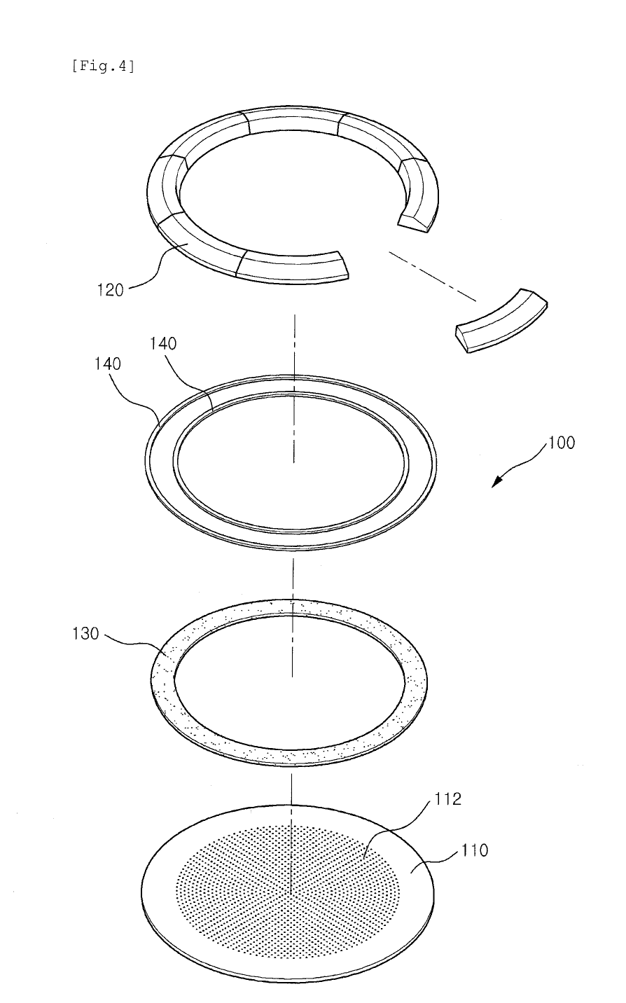

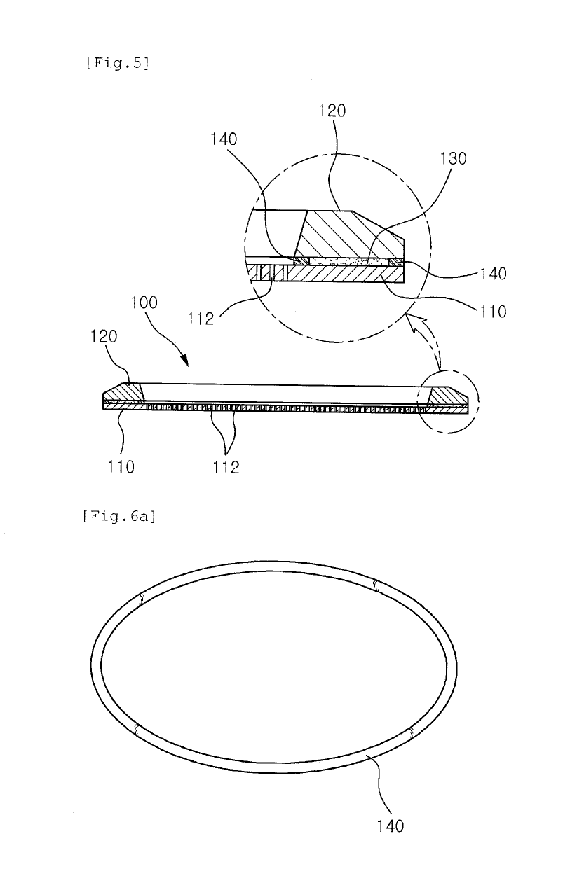

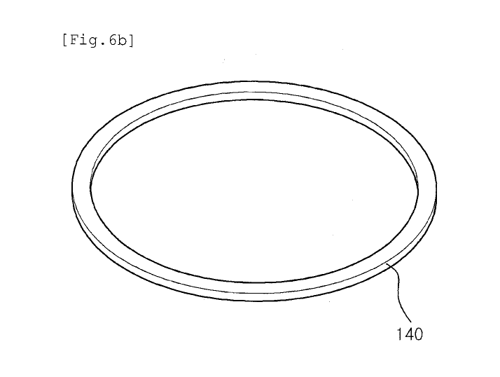

FIG. 4 is an exploded perspective view of a plasma shield for an electrode in accordance with the present invention, FIG. 5 is a cross-sectional view of the plasma shield for an electrode in accordance with the present invention, which is assembled, FIG. 6A is a perspective view showing a plasma shield applied to the plasma shield for an electrode in accordance with the present invention, and FIG. 6B is a perspective view showing another plasma shield applied to the plasma shield for an electrode in accordance with the present invention.

As shown in FIGS. 4 to 6, a plasma shield 140 for an electrode in accordance with the present invention seals and protects an elastomer, a double-sided adhesive 130 for attaching a gas injection plate 110 to an injection plate support member 120, to prevent separation of the adhesive 130 when a high pressure gas is injected through gas injection holes 112 of the gas injection plate 110, and protects the adhesive 130 from attacks of plasma to prevent generation of particles.

Therefore, as described above, the plasma shield 140 for an electrode in accordance with the present invention configured to prevent separation of the adhesive and generation of particles by protecting the adhesive 130 from attacks of the plasma can prevent contamination of a workpiece such as a wafer and improve quality of products by preventing generation of the particles when the workpiece is processed.

First, reviewing an electrode 100 for a plasma chamber in accordance with the present invention, as shown in FIGS. 4 and 5, the electrode 100 for a plasma chamber includes the gas injection plate 110 having a porous plate structure in which a plurality of gas injection holes 112 are formed, the injection plate support member 120 configured to maintain the gas injection plate 110 attached to one side of the plasma chamber 10, and the double-sided adhesive 130 formed of an elastomer material and attaching the injection plate support member 120 on the gas injection plate 110.

Here, the plasma shields 140 in accordance with the present invention are installed at inner and outer diameter sides of the adhesive 130 of the electrode 100 for a plasma chamber constituted by the gas injection plate 110, the injection plate support member 120 and the adhesive 130 to seal the adhesive 130. In addition, the plasma shields 140 have an annular shape having diameters corresponding to an inner diameter and an outer diameter of the elastomer, or the adhesive 130.

Meanwhile, in the diameters of the plasma shields 140 disposed at the inner and outer diameter sides of the adhesive 130 formed of elastomer, the outer diameter of the plasma shield 140 installed adjacent to the inner diameter side of the adhesive 130 has a diameter corresponding to the inner diameter of the adhesive 130, and the inner diameter of the plasma shield 140 installed adjacent to the outer diameter side of the adhesive 130 has a diameter corresponding to the outer diameter of the adhesive 130.

The plasma shield 140 in accordance with the present invention as described above may be formed of any one of perfluoroelastomer (FFKM), viton fluoroelastomer, silicon, and polyamide.

In addition, the plasma shields 140 installed at the inner and outer diameter sides of the adhesive 130 formed of elastomer are fixed to the inner and outer diameter sides of the adhesive 130 by coupling the gas injection plate 110 and the injection plate support member 120 integrated through adhesion and pressing of the adhesive 130.

Further, in the electrode 100 for a plasma chamber as described above, the plasma shields 140 disposed at the inner and outer diameter sides of the adhesive 130 formed of elastomer may be adhered to a lower surface of the injection plate support member 120 and an upper surface of the gas injection plate 110 through adhesive elements, or may be disposed at the inner and outer diameter sides of the adhesive to be fixed by adhesion of the gas injection plate 110 and the injection plate support member 120 by the adhesive 130.

The plasma shields 140 are installed adjacent to the inner diameter and the outer diameter of the adhesive 130 formed of elastomer to seal inner and outer sides of the adhesive 130, or the elastomer, between the gas injection plate 110 and the injection plate support member 120. As the inner diameter and the outer diameter of the adhesive 130 between the gas injection plate 110 and the injection plate support member 120 are sealed by the plasma shields 140, the adhesive 130 is protected from separation by a high pressure gas or attacks of plasma.

In other words, as described above, as the inner diameter and the outer diameter of the adhesive between the gas injection plate 110 and the injection plate support member 120 are sealed by the plasma shields 140, the adhesive 130 formed of elastomer is protected by the plasma shields 140 installed at inner and outer sides to prevent separation of the adhesive when a high pressure gas is injected, and protected from attacks of the plasma to prevent generation of particles.

Therefore, as described above, since the adhesive 130 formed of elastomer is protected by the plasma shields 140 installed at the inner and outer sides, resistance against the attacks of the plasma when the plasma chamber is operated is increased. Accordingly, the adhesive 130 formed of elastomer is protected from the attacks of the plasma even in a plasma state due to an operation of the plasma chamber.

Meanwhile, when a general plasma chamber is operated, the inside of the chamber enters a vacuum state and a reaction gas such as fluorine or nitrogen is injected through the gas injection holes, and when power is supplied from the power supply to apply a high voltage to the cathode (the electrode for a plasma chamber) and the anode, the inside of the chamber enters a plasma state. In this process, a workpiece such as a wafer is processed by a reaction gas in a plasma state through an etching or deposition process.

Therefore, in the present invention, as the plasma shields 140 configured to seal the inner and outer sides of the adhesive 130 formed of elastomer and disposed between the gas injection plate 110 and the injection plate support member 120 are installed at the inner and outer diameter sides of the adhesive 130 to protect the adhesive 130, separation of the adhesive 130 due to the injection of the high pressure gas and the attacks of the plasma is prevented to prevent generation of particles.

Meanwhile, reviewing the configuration of the plasma shields configured to seal the inner and outer sides of the adhesive 130 formed of elastomer and disposed between the gas injection plate 110 and the injection plate support member 120 as described above, as shown in FIG. 6A, each of the plasma shields 140 has an O-ring shape having a circular cross-section.

As shown in FIG. 6A, a diameter of the plasma shield 140 having an O-ring shape is equal to or larger than a thickness of the adhesive 130 such that outer circumferences of the plasma shields 140 having an O-ring shape are adhered to the upper surface of the gas injection plate 110 and the lower surface of the injection plate support member 120 by the adhesive 130 to seal a space between the plasma shields 140 disposed at the inner and outer sides.

Therefore, as shown in FIG. 6A, the plasma shields 140 having an O-ring shape and disposed at the inner and outer sides seal the adhesive 130 disposed therebetween to prevent contact with particles, protecting the adhesive 130 from the attacks of the plasma.

In addition, as shown in FIG. 6B, the plasma shields 140 configured to seal the inner and outer sides of the adhesive formed of elastomer and disposed between the gas injection plate 110 and the injection plate support member 120 may have a gasket shape having a rectangular cross-section.

As described above, the plasma shields 140 having a gasket shape shown in FIG. 6B have a thickness equal to or larger than the thickness of the adhesive 130 such that upper and lower surfaces of the plasma shields 140 having a gasket shape are adhered to the upper surface of the gas injection plate 110 and the lower surface of the injection plate support member 120 during a process of attaching and pressing the gas injection plate 110 to the injection plate support member 120 using the adhesive 130, sealing a space between the plasma shields 140 disposed at the inner and outer sides.

Of course, as described above, since the plasma shield 140 having an O-ring shape and the plasma shield 140 having a gasket shape as shown in FIGS. 6A and 6B are disposed in the plasma chamber in the plasma state, the plasma shields 140 are formed of a synthetic resin material having a thermal resistance that can endure a temperature in the plasma state.

As described above, the plasma shields 140 in accordance with the present invention can seal the adhesive 130 from the inner and outer diameter sides thereof to protect the adhesive from the high pressure gas and plasma to prevent generation of particles, improving a lifespan of the electrode 100 for a plasma chamber.

In addition, the plasma shields 140 in accordance with the present invention can protect the adhesive 130 from the high pressure gas and plasma to reduce a downtime due to malfunction of the electrode 100 for a plasma chamber, improving a rate of operation of the plasma chamber.

Further, the plasma shields 140 in accordance with the present invention can protect the adhesive 130 from the particles to increase an exchange cycle of the plasma shields 140, reducing exchange cost thereof.

As can be seen from the foregoing, the plasma shield for an electrode can prevent generation of particles by fixing plasma shields at inner and outer diameter sides of adhesive for attaching a gas injection plate to a gas injection plate support member to shield the adhesive from a high pressure gas or plasma.

In addition, the plasma shield for an electrode can improve resistance against attacks of plasma by shielding the adhesive from the high pressure gas or plasma through configuration of the plasma shields at the inner and outer diameter sides of the adhesive.

Further, the plasma shield for an electrode can improve a lifespan of an electrode for a plasma chamber by shielding the adhesive from the high pressure gas or plasma through configuration of the plasma shields at the inner and outer diameter sides of the adhesive.

Furthermore, the plasma shield for an electrode can reduce exchange needs of the plasma shield for an electrode by shielding the adhesive from the high pressure gas or plasma through configuration of the plasma shields at the inner and outer diameter sides of the adhesive.

While the invention has been shown and described with reference to certain example embodiments thereof, it will be understood by those skilled in the art that various changes in form and details may be made therein without departing from the spirit and scope of the invention as defined by the appended claims.

What is claimed is:

1. A plasma shield for an electrode, the electrode including a gas injection plate having a porous plate structure in which a plurality of gas injection holes are formed, an injection plate support member configured to maintain the gas injection plate attached to one side of a plasma chamber, and an adhesive formed of elastomer and attaching the injection plate support member to an upper surface of the gas injection plate,
the improvement comprising plasma shields having an annular shape corresponding to inner and outer diameters of the adhesive formed of the elastomer, installed adjacent to inner and outer diameter surfaces of the adhesive formed of the elastomer, and sealing the adhesive formed of the elastomer and disposed between the gas injection plate and the injection plate support member to protect the adhesive from a high pressure gas and plasma and prevent generation of particles.

2. The plasma shield for an electrode according to claim 1, wherein the plasma shield has an O-ring shape having a circular cross-section.

3. The plasma shield for an electrode according to claim 1, wherein the plasma shield has a gasket shape having a rectangular cross-section.

4. The plasma shield for an electrode according to claim 1, wherein the plasma shields are attached to a lower surface of the injection plate support member and an upper surface of the gas injection plate through adhesive elements, or disposed at inner and outer diameter sides of the adhesive to be fixed by adhesion of the gas injection plate and the injection plate support member due to the adhesive.

5. The plasma shield for an electrode according to claim 4, wherein the plasma shield is formed of any one of perfluoroelastomer (FFKM), viton perfluoroelastomer, silicon, and polyamide.
